(19) United States
(12) Patent Application Publication
(10) Pub. No.: US 2003/0017268 A1
(43) Pub. Date: Jan. 23, 2003

(54) .METHOD OF CVD TITANIUM NITRIDE FILM DEPOSITION FOR INCREASED TITANIUM NITRIDE FILM UNIFORMITY

(75) Inventors: Jianhua Hu, Sunnyvale, CA (US); Hanh D. Nguyen, San Jose, CA (US); Steve H. Chiao, San Jose, CA (US); Xiaoxiong Yuan, Cupertino, CA (US); Anzhong Chang, San Jose, CA (US); Hongbee Teoh, Saratoga, CA (US); Avgerinos Gelatos, Redwood City, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/908,999

(22) Filed: Jul. 18, 2001

(51) Int. Cl. C23C 16/00

(52) U.S. Cl. 427/255.391

(57) ABSTRACT

In one aspect of the present invention there is provided a method of improving the uniformity of a titanium nitride film, comprising the steps of introducing TiCl₄ gas to a chemical vapor deposition chamber from the center of a chamber lid wherein said chamber lid has a blocker plate; introducing NH₃ gas to the chemical vapor deposition chamber simultaneously from both the center and edge of the chamber lid thereby distributing the TiCl4 gas and the NH3 gas uniformly across a surface of a wafer; and depositing a titanium nitride film by chemical vapor deposition onto the surface of the wafer where the uniform distribution of the TiCl₄ gas and the NH₃ gas yields a titanium nitride film with improved uniformity. The chamber is provided with two pumping channels positioned on either side of the chamber.

### BACKGROUND OF THE INVENTION

1. Field of the Invention

The present invention relates generally to the field of semiconductor manufacturing. More specifically, the present invention relates to a method of improving uniformity of CVD titanium nitride films.

2. Description of the Related Art

With the scaling down of semiconductor features to the 0.25 micron level, uniformity of deposited films becomes increasingly more important. Also, the concomitant increase in semiconductor substrate diameters from 100 mm to 300 mm necessitates an increase in chamber size. Chemical vapor deposition (CVD) of thin films is a broad class of processes that uses controlled chemical reactions to create thin layers on wafers. CVD results in good step coverage and wafer-to-wafer repeatability on complicated topography of VLSI and ULSI devices.

In a CVD process, the process gases used to deposit a film must be delivered to the chamber and distributed over the wafer surface. In a typical CVD apparatus, gas delivery into the chamber proceeds through a gas distribution assembly 10 (FIG. 1). In such an assembly there is typically a gas manifold 20, a gas box 22 (or gas injection cover plate), a showerhead assembly 24, and an isolator 26, all of which are mounted on an electrically grounded chamber lid 38. The showerhead 24 can comprise a perforated blocker plate 30 and a faceplate 32 with an array of holes 34. Gases are diffused or passed through both the blocker plate 30 and the faceplate 32 thereby providing a uniform concentration of gases over the wafer surface. In addition, a cavity between the blocker plate 30 and the gas box 22 provides another agitation stage to continue mixing the process gases. O-rings 36, disposed between the various components, insure hermitic seals to prevent leakage of the gases.

If process gases can not be distributed uniformly to the chamber and with the increase in chamber size because of increased wafer size, variations in deposition rates and uniformity of the deposited films occur from the center to the edge of the wafer. Deposition uniformity has been improved by altering the gas flow profile over the wafer surface. In one such system the gas flow profile is controlled in parallel across the wafer, i.e, the apertures in the gas manifold are varied such that relatively more gas is flowed in through the center. Alternatively, valves adjust pairs of gas flows that merge into independent streams that are distributed laterally upstream of the wafer. Gases are flowed separately until just before the leading edge of the wafer thereby providing control over the flow and concentration profiles of the reactant and carrier gases used in the particular deposition process.

In a CVD process using reactive gases, it is particularly important to control how process gases are flowed into the chamber. In titanium nitride CVD applications, the film is deposited during the reaction of titanium chloride (TiCl₄) and ammonia (NH₃). The production of a thin conformal film with good uniformity is critically dependent on the flow profiles of the reactive precursor gases. The gases must be uniformly distributed over the large wafer surface. They must be introduced into the process chamber in such a way that no reaction occurs prior to flowing into the chamber, yet sufficient mixing and distribution must occur across the wafer surface to yield uniform deposition rates and conformal coverage. To achieve this type of process control and to improve titanium nitride film uniformity it is advantageous to further improve the distribution of TiCl₄ and NH₃ within the chamber and the pumping of the chamber.

Therefore, the prior art is deficient in the lack of effective means of improving uniformity of titanium chloride-based titanium nitride films. Specifically, the prior art is deficient in the lack of effective means of introducing TiCl₄ and NH₃ gases into a chamber such that uniformity of a CVD titanium nitride film is improved. The present invention fulfills these long-standing needs and desires in the art.

### SUMMARY OF THE INVENTION

An aspect of the present invention is a method of improving uniformity of a titanium nitride film deposited during a chemical vapor deposition (CVD) process by introducing TiCl₄ and NH₃ into the chamber through the center and edge of a chamber lid having a blocker plate. More particularly, TiCl₄ gas is introduced into the CVD deposition chamber from the center of the lid while NH₃ gas is introduced into the CVD chamber simultaneously from the center and the edge of the chamber lid at heater temperatures and chamber pressures conducive to CVD of a titanium nitride film

Another aspect is regulating the NH₃ gas introduced from the center of the chamber lid to a flow rate 20% of the total NH₃ flow rate. During CVD of the titanium nitride film, pumping is done from two pumping channels positioned on either side of the chamber. This aspect also provides the deposited titanium nitride film.

Another aspect is regulating the NH₃ gas introduced from the center of the chamber lid by the dimension of the distribution channel between the center and the edge of the lid or by the dimension of the center inlet holes on the lid so the flow rate of the NH₃ gas from the center of the chamber lid is about 20% of the total NH₃ flow. CVD of the titanium nitride film occurs at a heater temperature of about 550° C. to about 680° C. and at a chamber pressure of about 5 torr to about 20 torr. Pumping during the CVD process is done from two pumping channels positioned on either side of the chamber.

Other and further aspects, features, and advantages of the present invention will be apparent from the following description of the embodiments of the invention given for the purpose of disclosure.

### BRIEF DESCRIPTION OF THE DRAWINGS

So that the matter in which the above-recited features, advantages and objects of the invention, as well as others which will become clear, are attained and can be understood in detail, more particular descriptions of the invention briefly summarized above may be had by reference to certain embodiments thereof which are illustrated in the appended drawings. These drawings form a part of the specification. It is to be noted, however, that the appended drawings illustrate embodiments of the invention and therefore are not to be considered limiting in their scope.

FIG. 1 shows an expanded view of the components of a prior art gas distribution assembly for a CVD chamber.

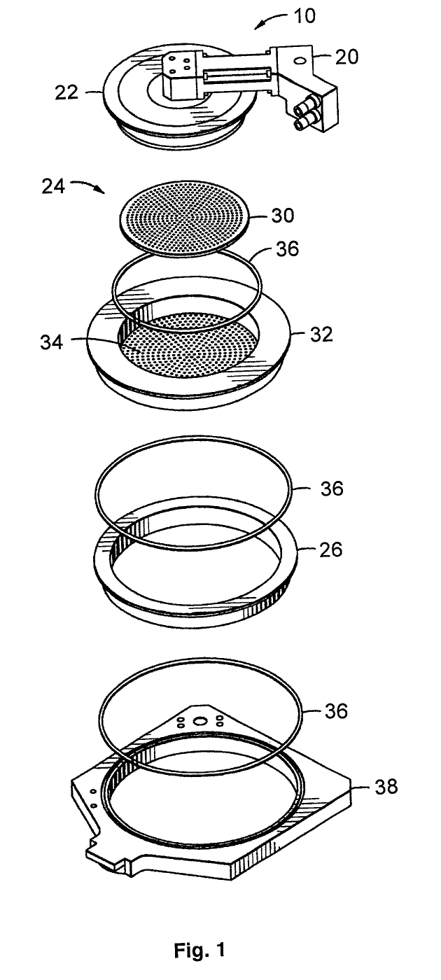

FIG. 2 shows a profile of the change in surface deposition rate of TiN as the radius of the distribution channel increases for various percentages of NH₃ center flow using a 300 mm HTTiN showerhead with central holes.

FIG. 3 shows a vertical cross-section of a chamber lid for a 300 mm TiCl₄—TiN chamber and flow simulations wherein the pumping port(s) are sized and positioned differently. Conditions for TiCl₄ based TiN deposition are 200 sccm NH3, 2000 sccm N2, 40 sccm TiCl₄ and 2000 sccm He. Heater temperature is 680° C. and chamber pressure is 10 Torr.

FIG. 4 shows the contour of pressure drop for each of the cases in FIG. 3.

FIG. 5 shows the contour of gas flow velocity for each of the cases in FIG. 3.

### DETAILED DESCRIPTION OF THE INVENTION

In one aspect of the present invention there is provided a method of improving the uniformity of a titanium nitride film, comprising the steps of introducing TiCl₄ gas to a chemical vapor deposition chamber from the center of a chamber lid wherein the chamber lid has a blocker plate; introducing NH₃ gas to the chemical vapor deposition chamber simultaneously from both the center and edge of the chamber lid thereby distributing the TiCl₄ gas and the NH₃ gas uniformly across a surface of a wafer; and depositing a titanium nitride film by chemical vapor deposition onto the surface of the wafer where the uniform distribution of the TiCl₄ gas and the NH₃ gas yields a titanium nitride film with improved uniformity. The NH₃ gas flow from the center of the lid may be regulated to about 20% of the total NH₃ flow. Representative techniques to regulate the center NH₃ gas flow are, for example, by the dimension of the distribution channel between the center and edge of the lid or by the dimension of the center inlet holes on the lid. During titanium nitride deposition pumping from two pumping channels positioned on either side of the chamber is also provided. The pumping channels may be symmetrically positioned.

In this aspect CVD of titanium nitride is performed at a heater temperature from about 550° C. to about 680° C. and at a chamber pressure of about 5 Torr to about 20 Torr. Representative examples are a heater temperature of about 680° C. and chamber pressure of about 10 Torr.

In another aspect of the present invention there is provided a method of improving the uniformity of a titanium nitride film comprising the steps of introducing TiCl₄ gas to a CVD chamber from the center of a chamber lid wherein the chamber lid has a blocker plate; introducing NH₃ gas to the CVD chamber simultaneously from both the center and edge of the chamber lid, wherein the NH₃ gas introduced from the center of the chamber lid is regulated to flow at about 20% of the total NH₃ gas flow; depositing a titanium nitride film by CVD on the surface of the wafer; and while depositing the titanium nitride film, pumping from two pumping channels positioned on either side of the chamber wherein the combination of the uniform dispersion of the TiCl₄ and NH₃ gases and of the pumping of the chamber during CVD deposition yields a titanium nitride film with improved uniformity.

In this particular aspect the center NH₃ gas flow may be regulated by the dimension of distribution channel between the center and the edge of the lid or by the dimension of the center inlet holes on the lid. The pumping channels may be symmetrically positioned. CVD of titanium nitride is performed at a heater temperature from about 550° C. to about 680° C. and at a chamber pressure of about 5 Torr to about 20 Torr. For example, the heater temperature is about 680° C. and the chamber pressure is about 10 Torr.

In yet another aspect of the present invention there is provided a method of improving the uniformity of a titanium nitride film comprising the steps of introducing TiCl₄ gas to a CVD chamber from the center of a chamber lid wherein the chamber lid has a blocker plate; introducing NH₃ gas to the CVD chamber simultaneously from both the center and edge of the chamber lid, wherein the NH₃ gas introduced from the center of the chamber lid is regulated by the dimension of the distribution channel between the center and the edge of the lid or by the dimension of the center inlet holes on the lid to flow at about 20% of the total NH₃ flow; depositing a titanium nitride film by CVD on the surface of the wafer where the heater temperature is from about 550° C. about 680° C. and the chamber pressure is from about 5 torr to about 20 torr; and while depositing the titanium nitride film, pumping from two pumping channels positioned on either side of the chamber wherein the combination of the uniform dispersion of the TiCl₄ and NH₃ gases and of the pumping of the chamber during CVD deposition yields a titanium nitride film with improved uniformity. The pumping channels may be symmetrically positioned.

In yet another aspect of the present invention there is provided a titanium nitride film deposited by the methods disclosed supra.

The following examples are given for the purpose of illustrating various embodiments of the invention and are not meant to limit the present invention in any fashion.

### EXAMPLE 1

### Uniform Distribution Improvement from TiCl₁ Center Flow and NH₃ Center Flow

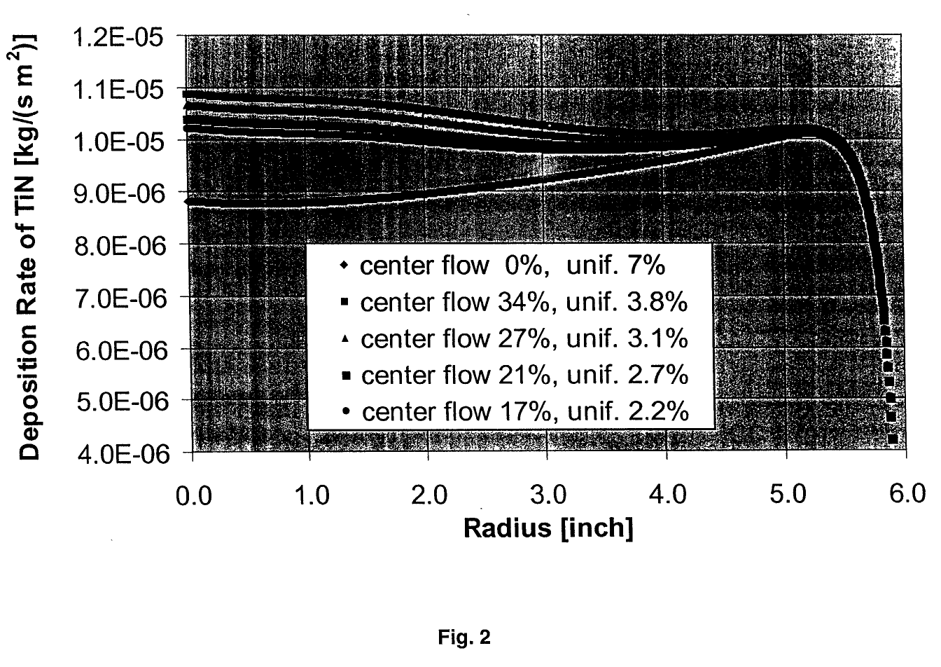

TiCl₄ introduction from the center of the lid with a blocker plate provides uniform TiCl₄ distribution across the wafer surface. Uniformity of gas distribution across the wafer surface is improved after incorporating NH₃ introduction through the center of the chamber lid together with NH₃ introduction from the edge of the lid. Computer modeling (FIG. 2) shows that NH₃ distribution uniformity is 7% with NH₃ introduction only from the edge of the lid. NH₃ distribution improved to 2.2% when center NH₃ flow is increased to 17%. However, further increase of center NH₃ flow to 34% increases distribution uniformity across the wafer surface worse to about 3.8%. To keep NH₃ flow optimal the hardware design incorporates a control mechanism such as the dimension of the distribution channel between the center and the edge of the lid or the dimension of the center inlet holes to make the center NH₃ flow around 20% of the total NH₃ flow.

### EXAMPLE 2

### Location of Pumping Ports

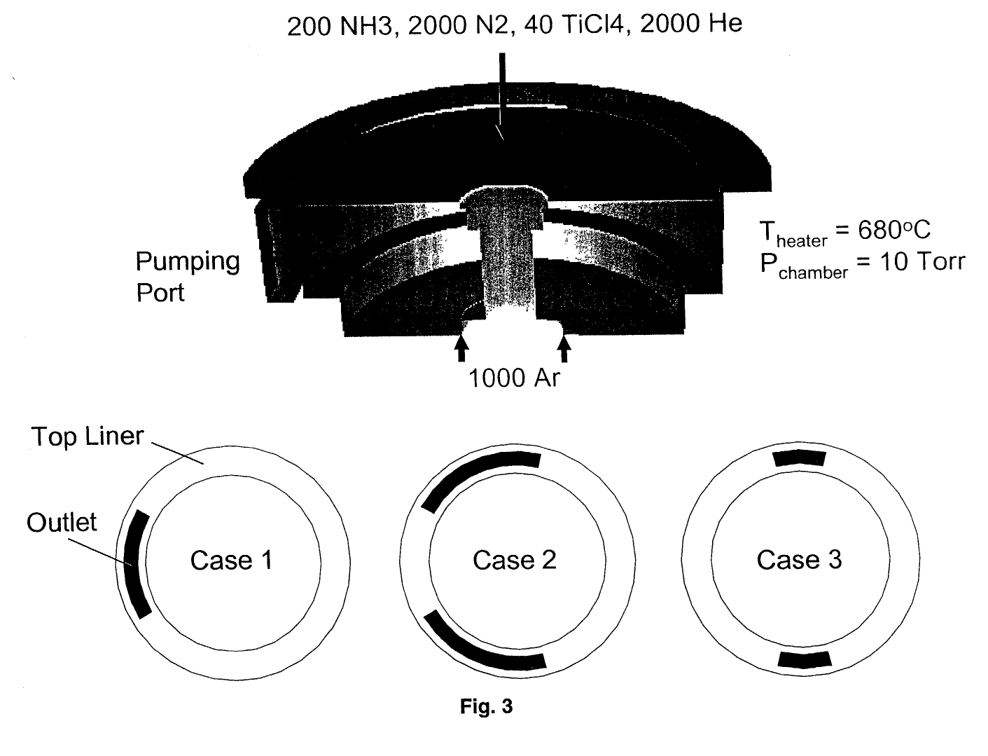

During a CVD deposition process a pumping port is provided to pump unreacted process gases and unwanted byproducts from the system to prevent incorporation of impurities and to keep process gases flowing evenly across the wafer surface. FIG. 3 is a vertical cross-section of the gas distribution assembly in a 300 mm TiCl₄—TiN chamber depicting process and carrier gas flow. Typically, the pumping port is located on the side of the chamber opposite the slit valve (Case 1, FIG. 3). Computer modeled simulations optimize the pumping port numbers, location and size for improved gas distribution uniformity across the wafer surface. Case 2 positions two pumping ports not quite on opposite sides of the chamber; Case 3 locates two smaller pumping ports on directly opposite sides of the chamber.

### EXAMPLE 3

### Simulation of Pressure Drop with Pumping Port Location

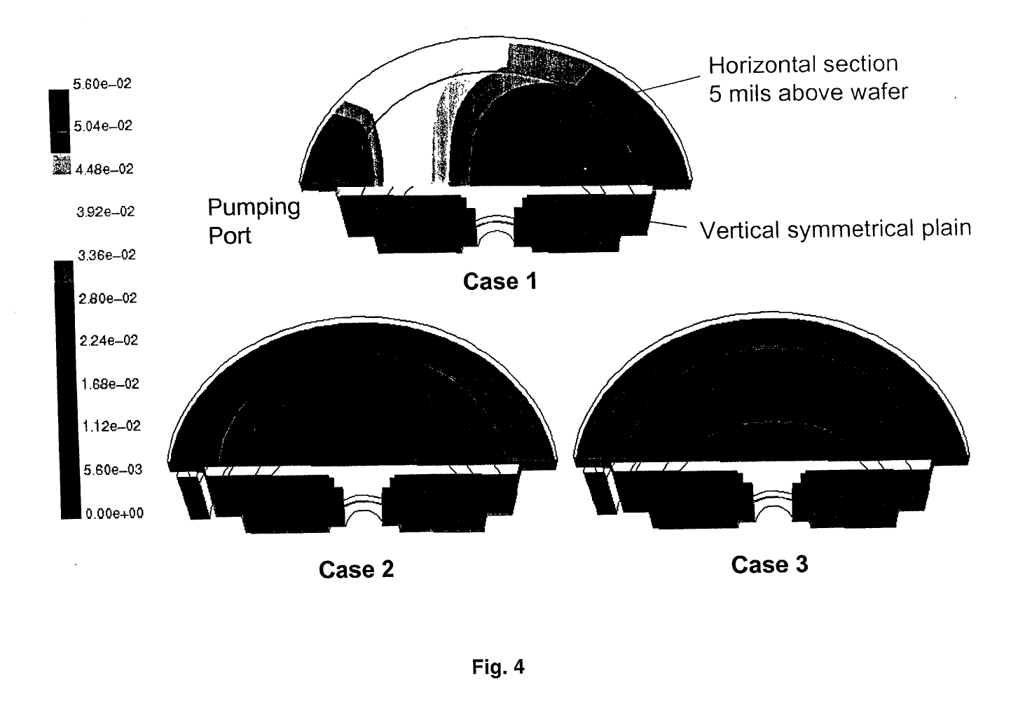

The vacuum generated by pumping out unreacted gases or byproducts during CVD deposition can increase the mean free path of the depositing molecules across the wafer surface possibly resulting in a more uniform and controllable deposited film. However, it is important that the pressure across the wafer surface does not drop; uniform pressure allows even gas distribution and concomitant uniform film deposition. FIG. 4 shows contour profiles of the pressure drop across the wafer surface for each of the pumping port(s) placement depicted in FIG. 3.

Pumping only from the side opposite to the slit valve (FIG. 4, Case 1) gives more than twice as big a pressure drop across wafer surface as pumping from two ports on the side of the chamber. Having two pumping ports on the side of the chamber as in Cases 2 and 3 keeps pressure drop across the wafer to a minimum.

### EXAMPLE 4

### Simulation of Gas Flow Velocity with Pumping Port Location

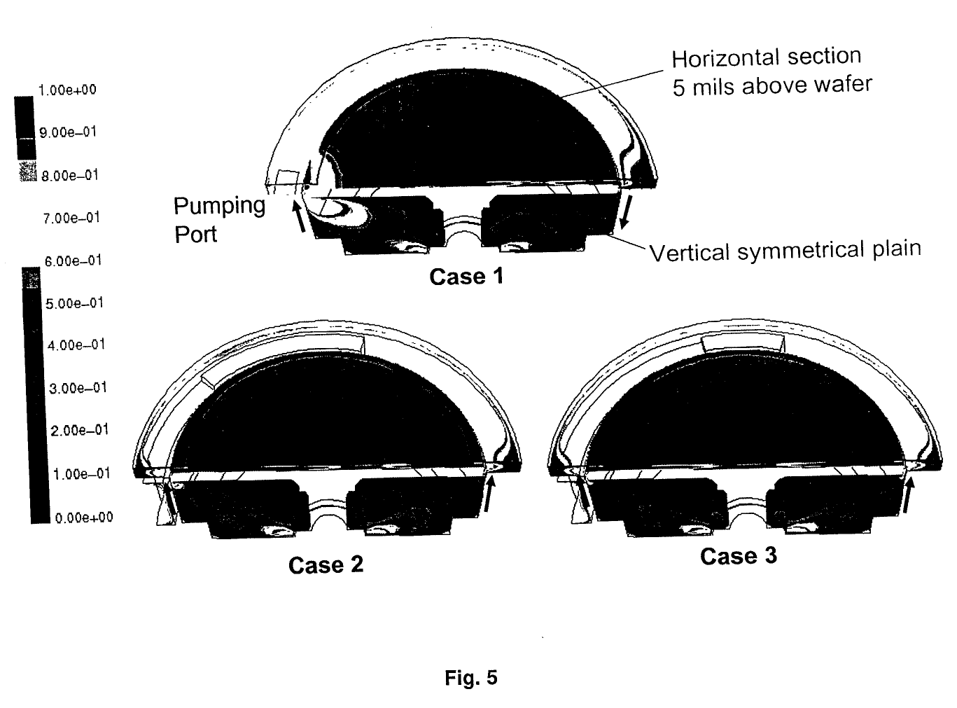

Gas flow velocity affects uniformity across the wafer surface. Changes in gas flow velocity across the surface of a wafer change the deposition rate at any particular part of the wafer. Gas flow velocity is also more uniform with two pumping ports on the side of the chamber. As can be seen in FIG. 5, Case 1, the change in velocity of the gases across the wafer is significantly greater nearer the single pumping port. Pumping from two ports as depicted in Cases 2 and 3 causes the change in gas flow velocity across the wafer to vary little from the center of the wafer to the periphery.

One skilled in the art will readily appreciate that the present invention is well adapted to carry out the objects and obtain the ends and advantages mentioned, as well as those inherent therein. It will be apparent to those skilled in the art that various modifications and variations can be made in practicing the present invention without departing from the spirit or scope of the invention. Changes therein and other uses will occur to those skilled in the art which are encompassed within the spirit of the invention as defined by the scope of the claims.

What is claimed is:

1. A method of improving the uniformity of a titanium nitride film, comprising the steps of:
introducing TiCl₄ gas into a chemical vapor deposition chamber from the center of a chamber lid wherein the chamber lid has a blocker plate;
introducing NH₃ gas to the chemical vapor deposition chamber simultaneously from both the center and edge of the chamber lid thereby distributing the TiCl₄ gas and the NH₃ gas uniformly across a surface of a wafer; and
depositing a titanium nitride film by chemical vapor deposition onto the surface of the wafer wherein the uniform distribution of the TiCl₄ gas and the NH₃ gas yields a titanium nitride film with improved uniformity.

2. The method of claim 1, wherein the NH₃ gas introduced from the center of the chamber lid is regulated to flow at about 20% of the total NH₃ gas flow.

3. The method of claim 2, wherein the center NH₃ gas flow is regulated by the dimension of the distribution channel between the center and the edge of the lid or by the dimension of the center inlet holes on the lid.

4. The method of claim 1, wherein chemical vapor deposition is performed at a heater temperature of about 550° C. to about 680° C.

5. The method of claim 4, wherein the heater temperature is 680° C.

6. The method of claim 1, wherein chemical vapor deposition is performed at a chamber pressure of about 5 Torr to about 20 Torr.

7. The method of claim 6, wherein the chamber pressure is 10 Torr.

8. The method of claim 1, further comprising the step of pumping from two pumping channels positioned on either side of the chamber during CVD of the titanium nitride film.

9. The method of claim 8, wherein the pumping channels are symmetrically positioned.

10. A method of improving the uniformity of a titanium nitride film comprising the steps of:
introducing TiCl₄ gas to a CVD chamber from the center of a chamber lid wherein said chamber lid has a blocker plate;
introducing NH₃ gas to the CVD chamber simultaneously from both the center and edge of the chamber lid, wherein the NH₃ gas introduced from the center of the chamber lid is regulated to flow at about 20% of the total NH₃ flow;
depositing a titanium nitride film by CVD on the surface of the wafer; and
while depositing the titanium nitride film, pumping from two pumping channels positioned on either side of the chamber wherein the combination of the uniform dispersion of the TiCl₄ and NH₃ gases and of the pumping of the chamber during CVD deposition yields a titanium nitride film with improved uniformity.

11. The method of claim 10, wherein the center NH₃ gas flow is regulated by dimension of the distribution channel between the center and the edge of the lid or by the dimension of the center inlet holes on the lid.

12. The method of claim 10, wherein CVD is performed at a heater temperature from about 550° C. to about 680° C.

13. The method of claim 12, wherein the heater temperature is 680° C.

14. The method of claim 10, wherein CVD is performed at a chamber pressure from about 5 Torr to about 20 Torr.

15. The method of claim 14, wherein the chamber pressure is 10 Torr.

16. The method of claim 10, wherein the pumping channels are symmetrically positioned.

17. A method of improving the uniformity of a titanium nitride film comprising the steps of:
introducing TiCl₄ gas to a CVD chamber from the center of a chamber lid wherein said chamber lid has a blocker plate;
introducing NH₃ gas to the CVD chamber simultaneously from both the center and edge of the chamber lid, wherein the NH₃ gas introduced from the center of the chamber lid is regulated by the dimension of the distribution channel between the center and the edge of the lid or by the dimension of the center inlet holes on the lid to flow at about 20% of the total NH₃ flow;
depositing a titanium nitride film by CVD on the surface of the wafer wherein the heater temperature is from about 550° C. about 680° C. and the chamber pressure is from about 5 torr to about 20 torr; and
while depositing the titanium nitride film, pumping from two pumping channels positioned on either side of the chamber wherein the combination of the uniform dispersion of the TiCl₄ and NH₃ gases and of the pumping of the chamber during CVD deposition yields a titanium nitride film with improved uniformity.

18. The method of claim 17, wherein the pumping channels are symmetrically positioned.

19. A titanium nitride film formed by the method of claim 10.
